(19) United States
(12) Patent Application Publication
(10) Pub. No.: US 2021/0006235 A1
(43) Pub. Date: Jan. 7, 2021

(54) Compensation Filter and Method for Activating a Compensation Filter

(71) Applicant: TDK Electronics AG, Munich (DE)

(72) Inventor: Yasin Karinca, Giengen (DE)

(21) Appl. No.: 16/970,276

(22) PCT Filed: Jan. 15, 2019
(86) PCT No.: PCT/EP2019/050948

§ 371 Date: Aug. 14, 2020

(30) Foreign Application Priority Data
Feb. 15, 2018 (DE) 10 2018 103 391.5

(51) Int. Cl. H03H 11/12; H02H 1/04; H03H 1/00; H02H 9/00

(52) U.S. Cl. CPC H03H 11/126; H02H 1/04; H02M 1/44; H02H 9/005; H03H 1/0007

(57) ABSTRACT

A compensation filter and a method for activating a compensation filter are disclosed. In an embodiment a compensation filter includes a power supply line, an electrical amplifier, an output-coupling circuit between the power supply line and an input of the electrical amplifier, an input-coupling circuit between an output of the amplifier and the power supply line, and a time switch. The time switch is connected in series with the input-coupling circuit between the output of the amplifier and the power supply line.

This patent application is a national phase filing under section 371 of PCT/EP2019/050948, filed Jan. 15, 2019, which claims the priority of German patent application 102018103391.5, filed Feb. 15, 2018, each of which is incorporated herein by reference in its entirety.

### TECHNICAL FIELD

The invention relates to compensation filters, which can be used, for example, to reduce interference such as leakage currents, and relates to methods for activating said compensation filters.

### BACKGROUND

Electrical loads can be connected to a power source, for instance to a power grid. Different categories of currents can flow in such electrical systems. On the one hand, there is the flow of the usual currents for operating the electrical load. On the other hand, unwanted currents, for instance fault currents, may arise if the housing is connected to a conducting phase. These are a health hazard to associated users of the electrical loads and must be prevented. Leakage currents constitute a third category. A leakage current is an electrical current that under normal operating conditions flows in an unwanted current path.

Leakage currents constitute a specific form of common-mode currents. In equipment comprising ground fault circuit interrupters (GFCI), which are intended to protect the health of the user concerned, leakage currents often lead to problems, because they can cause the ground fault circuit interrupter to trip and thereby disrupt reliable operation.

European Patent Application No. EP3113361 A1 discloses circuits that can be used to reduce leakage currents.

Another option for preventing leakage currents from tripping ground fault circuit interrupters is to use isolation transformers. An isolation transformer is often deployed to prevent ground fault circuit interrupters tripping as a result of static leakage currents. The galvanic isolation means that the leakage current flows almost entirely on the secondary side of the isolation transformer, and therefore is not detected by the ground fault circuit interrupter, which sits on the primary side. Deploying isolation transformers is undesirable, however, because of several disadvantages. At higher rated currents, the overall size increases significantly, making the isolation transformer large and heavy. This can be a disqualification criterion especially for mobile machinery, for instance. High power losses and associated high temperatures are further disadvantages of isolation transformers.

Another option is to use a power cable that has a fixed connection. It is then possible to dispense with a ground fault circuit interrupter. The drawback here, however, is that the equipment or machinery is fixed to a location.

Electrical energy can be provided by a three-phase line. In the process of plugging in the power cable to a 400 V grid, a line imbalance occurs briefly, which may result in the neutral-point voltage of the capacitive connection to the grid being non-zero at the moment of plugging-in. This is another possible way in which a transient leakage current causes the ground fault circuit interrupter to trip.

### SUMMARY

Embodiments provide compensation circuits which are configured to attenuate common-mode interference such as leakage currents in a power supply line, for instance, and which are configured to allow an electrical load to be used after a ground fault circuit interrupter in a plug-in manner.

A compensation filter has a first port, a second port, and a power supply line between the first port and the second port. In addition, the compensation filter has an electrical amplifier having an input and an output. Furthermore, the filter has an output-coupling circuit, which is connected between the power supply line and the input of the amplifier, and an input-coupling circuit, which is connected between the output of the amplifier and the power supply line. The compensation filter also has a time switch. The compensation filter is intended to attenuate common-mode interference in the power supply line. The time switch is connected in series with the input-coupling circuit between the output of the amplifier and the power supply line.

The compensation filter thus makes it possible to attenuate common-mode interference by means of a loop consisting of output-coupling circuit, amplifier and input-coupling circuit. Interference in the power supply line is transferred at least in part to the amplifier via the output-coupling circuit. The amplifier outputs a compensation signal, which is coupled into the power supply line via the input-coupling circuit. The gain is preferably such that for a particular interference signal, a corresponding compensation signal is generated of the same frequency, the same phase and the same amplitude but opposite sign.

Said amplifier may comprise electronic circuit components. For instance, the amplifier can contain an operational amplifier.

It has been found that using such an amplifier results in transient phenomena. In other words, it takes a certain amount of time before the subcircuit of the compensation filter comprising input-coupling circuit, amplifier and output-coupling circuit is operating effectively. During this time, interference in the power supply line may potentially not be attenuated to a sufficient degree. By connecting the time switch in series with the input-coupling circuit between the output of the amplifier and the power supply line, it is possible to prevent the amplifier from being switched in, i.e. the switch being closed, until transient phenomena have finished and the amplifier, together with its electronic components, is working in the required manner.

If an electrical load is being connected to a power source, for instance by a three-phase line, via a plug-in connection, then it is possible for contact to be made with different phases at slightly different time instants. The associated line imbalance in the power supply line would then cause the neutral-point voltage of the capacitive connection to the grid of the active circuit components of the compensation filter to become non-zero at the moment of plugging-in. This would result in a high transient leakage current at the connection to the grid, which might cause the ground fault circuit interrupter to trip.

Using the time switch in series with the input-coupling circuit between the output of the amplifier and the power supply line suppresses precisely this non-zero neutral-point voltage of the connection to the grid, with the result that electrical loads that cause a leakage current can be used in a plug-in manner with a power source comprising a ground fault circuit interrupter.

It is possible in this case that the input-coupling circuit comprises a capacitive element.

Said capacitive element may be formed by a capacitor having the input-coupling capacitance Cₒ or comprise a corresponding input-coupling capacitance.

For a single-phase power supply line, a single capacitor suffices as the capacitive element.

If the power supply line consists of a plurality of conductors of different phase, then the input-coupling circuit may have a more complex circuit topology. In this case, at least the neutral point of the power supply line can be coupled via at least one capacitive element of the input-coupling circuit to the amplifier via the time switch.

Common-mode interference can be categorized according to its frequency. Common-mode interference in a frequency range between 50 Hz and one kHz is designated as (quasi) static. Varying interference, for instance caused by the switching of inverters, has a frequency between 1 kHz and several kilohertz. What is known as transient interference has a wide frequency spectrum. Such interference is produced, for example, when an electrical load is switched on, and results generally from one-off, momentary processes.

Common-mode interference at a frequency equal to the grid frequency of the power source, for instance common-mode interference at 50 or 60 Hz, is particularly significant. This interference is critical in the sense that it affects the operational safety of the electrical load. In particular the aforementioned interference in the second category is generally at the grid frequency. The compensation filter must not attenuate common-mode interference at the grid frequency because in the case of this interference, the ground fault circuit interrupter must remove the electrical load from the grid immediately.

Conventional condensation circuits generally respond in a less frequency-selective manner in this situation. For circuitry reasons, it is advantageous in conventional compensation circuits preferably to select the coupling capacitance Cₒ to be as small as possible.

In order to guarantee that a ground fault circuit interrupter works safely for a grid frequency, it is therefore proposed in the present compensation filter to select the capacitance to be sufficiently large.

It is therefore possible that the capacitance Cₒ of the capacitive element of the input-coupling circuit is large enough for there to be compensation of leakage currents also below 1 kHz but preferably no compensation of leakage currents at the grid frequency.

It is possible that the output-coupling circuit comprises a first inductive element and a second inductive element. Said second inductive element is magnetically coupled to said first inductive element.

The first inductive element may be a coil or may comprise a coil, which is coupled or connected magnetically to the power supply line or to a conductor of the power supply line. The second inductive element of the output-coupling circuit is preferably connected directly or indirectly to the amplifier.

Depending on how large a proportion of the power is transferred to the amplifier by the output-coupling circuit, the gain of the amplifier is selected such that the condensation signal, which is returned to the power supply line, is of the same magnitude as the interference itself, in order that the current signal provided by the amplifier compensates the interference signal preferably in full.

It is possible that the amplifier comprises an operational amplifier, that a first resistive element is coupled between input-coupling circuit and the output of the amplifier, and that a second resistive element is connected between the input-coupling circuit and the input of the amplifier.

It is possible that for common-mode interference in the power supply line, the compensation filter transfers to the power supply line a compensation signal of the same frequency, same amplitude and inverse sign.

It is accordingly also possible that said common-mode interference starts in a critical frequency range above a grid frequency.

It is also possible that said common-mode interference contains a leakage current or consists of a leakage current.

In addition, it is possible that the compensation filter has a supply circuit for the amplifier.

The supply circuit is used to supply electrical power to the amplifier, i.e. to circuit components of the amplifier. In particular if the amplifier comprises electronic circuit components such as operational amplifiers, for example, then these need a supply of electrical power.

Said supply circuit for the amplifier can supply the amplifier with a DC voltage of approximate magnitude 48 V. Said supply circuit can comprise a voltage source comprising an AC/DC switched mode power supply.

Said supply circuit for the amplifier may itself comprise a dedicated supply input connection. This can be fed with energy from the power supply line or by an external power source.

The supply circuit can also act alternatively or additionally as the supply circuit for the time switch.

It is possible that the time switch comprises a relay and an actuating circuit for the relay.

It is possible that the actuating circuit for the relay works autonomously. The actuating circuit working autonomously means here that there is no need for any additional open-loop and closed-loop control lines from external logic circuitry. The control circuit starts operating automatically as soon as it is supplied with a sufficiently high supply voltage.

A semiconductor switch can also be used alternatively or additionally to the relay.

It is possible that the actuating circuit is connected to the relay and has a power supply connection, e.g., for the relay. It is also possible that the actuating circuit comprises a series RC network.

Said series RC network has at least a resistive element and a capacitive element.

The capacitive element can be charged or discharged via the resistive element. The length of time taken by the charging or discharging largely determines the time delay after which the time switch couples the amplifier to the power supply line via the input-coupling circuit.

Said delay of the time switch is preferably at least so large that transient phenomena have largely come to an end in the amplifier, and the amplifier is working properly.

The transient phenomena may require a time delay of 0.1 s, 0.5 s, 1 s, 1.5 s, 2 s or 5 s in this context. The resistance value of the resistive element and the capacitance value of the capacitive element are accordingly selected to prevent a critical switching voltage for the relay being reached before the intended delay period has elapsed.

It is possible that the resistive element has a resistance of 1.8 kΩ, while the capacitive element has a capacitance of 560 mF. The RC network is operated in this case by a rated voltage of magnitude 48 V. As soon as a critical voltage of, for instance, 33.6 V lies across the capacitive element, the connected relay switches and couples the amplifier to the power supply line via the input-coupling circuit.

The actuating circuit may also comprise a first diode, a second resistive element, and a second diode.

Said first diode can be connected in parallel with the resistive element of the series RC network. The second diode can connect to ground the electrode of the capacitive element of the RC network, which electrode is connected to the resistive element of the RC network. Said second diode may be a Zener diode for a critical voltage of 48 V. This provides a protective circuit for the actuating circuit, so that over-voltages can be diverted to ground.

The first diode is used to prevent too long a delay in opening the relay when the compensation filter is turned off. As soon as the supply voltage to the actuating circuit ceases to exist or is less than the coil voltage of the relay, the first diode starts to conduct, with the result that the charge of the capacitive element of the RC network can discharge more quickly via the diode.

The second resistive element can act as a pull-down resistor, so that a defined voltage value with respect to ground always lies across the coil of the relay if the supply voltage for the actuating circuit assumes an undefined value.

It is possible that the time switch is intended to couple the output of the amplifier to the power supply line only after a suitable delay of 0.1 s or more after the compensation filter is turned on.

By means of the compensation filter described above, it is possible to prevent the transient leakage current at the capacitive connection to the grid during plugging-in. When there is no phase voltage lying across the active compensation filter, the relay is open, with the result that the electronics are galvanically isolated from the grid. From the instant in time at which the power cable is plugged in and hence the phase voltage lies across the filter, it takes 1.8 s, for example, before the relay closes, and the electronics thereby are galvanically connected to the grid. Since the relay is switched with a time delay, this ensures that any line imbalance no longer exists and hence the neutral-point circuit lies at about 0 V with respect to ground. A high transient leakage current is thereby prevented from occurring at the active compensation filter.

The pull-down resistor may have a value of 5.52 kΩ. The relay may have a pickup voltage of 33.6 V and a dropout voltage of 4.8 V DC. The time delay is achieved by means of the RC network. The component dimensioning is chosen here such that the time delay equals approximately 0.1 s, 0.2 s, 0.5 s, 1 s, 1.5 s, 1.8 s, 2 s or more. Said time delay does not necessarily equal a specific external setting but can be chosen empirically so that after the power cable is plugged in, a sufficiently long time passes to guarantee reliable activation of the compensation filter.

Component tolerances may result in a slightly different time delay. In this case, the values must be chosen such that even given tolerance-related variations, the time delay is long enough.

Embodiments provide a method for activating a compensation filter having an amplifier and a power supply line. The method comprises at least the steps: coupling the power supply line to a power source and/or to an electrical load; and delaying a coupling between amplifier and power supply line.

### BRIEF DESCRIPTION OF THE DRAWINGS

Core aspects of the compensation filter and details of preferred embodiments are shown in the schematic figures, in which:

FIG. 1 is an equivalent circuit of a simple embodiment of the compensation filter;

FIG. 2 is an equivalent circuit of an embodiment having a supply circuit, in which the power supply line comprises three conductors;

FIG. 3 shows a simple embodiment of an actuating circuit for the time switch; and

FIG. 4 shows typical voltage curves during turn-on and turn-off of the actuating circuit.

### DETAILED DESCRIPTION OF ILLUSTRATIVE EMBODIMENTS

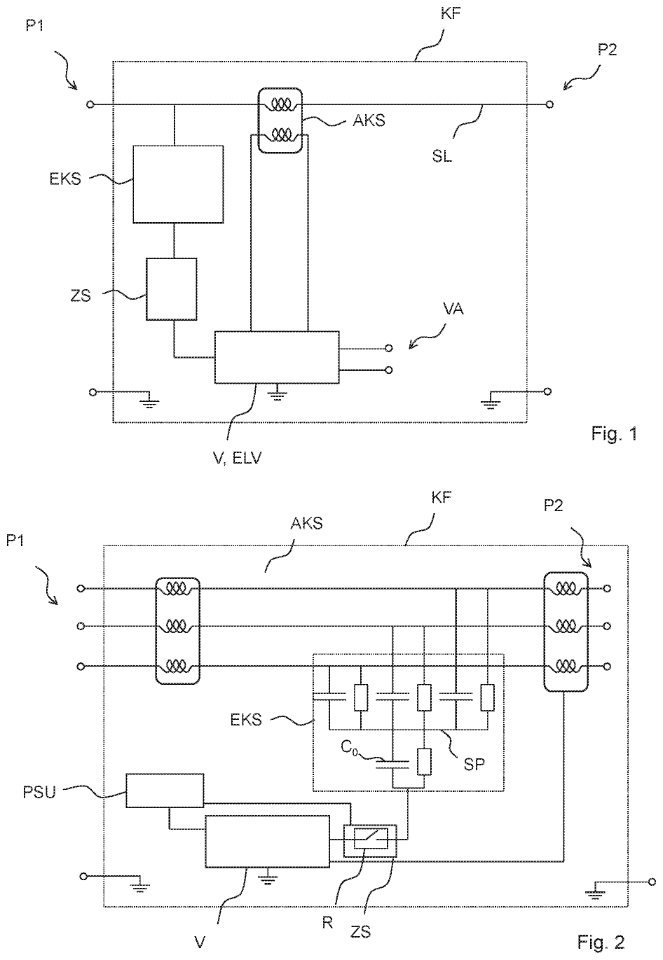

FIG. 1 shows the equivalent circuit of a simple embodiment of the compensation filter KF. The compensation filter KF has a first port P1 and a second port P2. A power supply line SL is connected therebetween. In addition, the compensation filter KF comprises an amplifier, for instance an electronic amplifier ELV comprising electronic circuit components, for example an operational amplifier. The output-coupling circuit AKS is connected between the power supply line SL and the amplifier V. The input-coupling circuit EKS is connected between the amplifier V and the power supply line SL. The time switch ZS is connected between the amplifier V and the input-coupling circuit EKS.

The amplifier V can be supplied with electrical power via a supply connection VA.

The time switch ZS is used to conduct the compensation signal formed by the amplifier to the power supply line via the input-coupling circuit EKS only once transient processes in the amplifier V have come to an end and the amplifier V has starting working in full.

The output-coupling circuit AKS comprises coupled inductive elements in order to pass electrical power representative of the interference signal to the amplifier V.

FIG. 2 illustrates the possibility of providing different phases in the power supply line SL. FIG. 2 accordingly shows an embodiment in which the power supply line SL has three different conductors. The first port accordingly consists of three individual connections. The second port P2 also has three individual connections. The input-coupling circuit EKS has a neutral point SP, which ideally lies at the same electrical potential as ground. The neutral point SP is coupled to the amplifier V via a parallel circuit composed of a resistive element and the coupling capacitance CO. The time switch ZS, which can comprise a relay R or an electronic power switch, is connected therebetween. The switch of the time switch ZS is controlled here by an actuating circuit. The time switch ZS and the amplifier V are supplied with electrical power by a shared supply circuit PSU. Said supply circuit PSU may itself be supplied with electrical power from an external power source or by extracting electrical power from the power supply line SL.

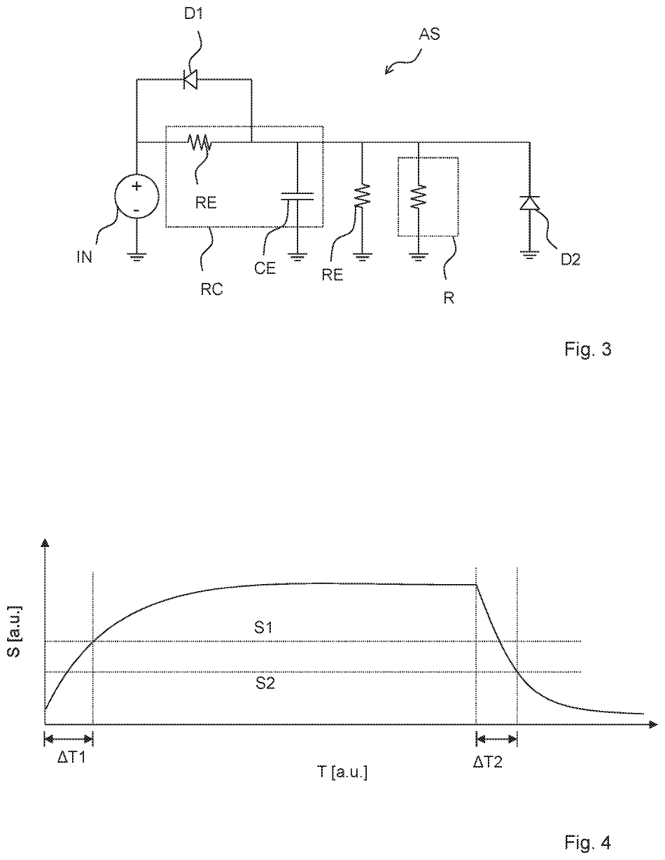

FIG. 3 shows a possible topology of an actuating circuit AS for the relay R. The actuating circuit AS has a power input IN and an RC network RC. The RC network RC has a resistive element RE and a capacitive element CE, which are connected in series. If the actuating circuit AS is turned on, the capacitive element CE of the RC network RC is charged via the resistive element RE. This charging causes a time delay, after which a sufficiently high voltage to operate the relay lies across the coil of the relay R. A second resistive element RE serves as a pull-down resistor in order to assign a defined potential to the node between the resistive element RE and the capacitive element CE of the RC network RC in case a defined input voltage is not applied to the actuating circuit at the input IN.

The diode D1 is used to discharge the capacitive element CE of the RC network RC more quickly when the actuating circuit AS is turned off. The diode D2 serves as a protective element for protecting the circuit in the event of too high a voltage lying at the input IN.

The coil of the relay R acts in the actuating circuit AS effectively as a resistive element.

FIG. 4 shows voltage curves over time during turn-on and turn-off of the actuating circuit AS. After a time interval ΔT1 after the actuating circuit AS of FIG. 3 is turned on, the voltage lying across the capacitive element CE of the RC network is high enough for a first critical voltage S1 to be reached. The voltage lying across the coil of the relay R in this case is now sufficient to turn on the relay and to couple the amplifier V to the power supply line SL.

A time difference ΔT2 after the actuating circuit AS is turned off, i.e. after the voltage is removed from the input IN, the capacitive element CE of the RC network RC is discharged via the diode to such an extent that there is a drop in voltage to below a second critical voltage S2, with the result that the relay R disconnects again the connection between amplifier V and power supply line SL via the input-coupling circuit EKS.

Achieving the delay ΔT1 in turning on the actuating circuit when the compensation filter is turned on means that the amplifier V is given enough time to settle and to reach the intended way of working.

In particular, interference situations caused by leakage currents when plugging in the power cable—if the electrical load is connected directly to the second port—are thereby prevented, and the electrical load can be operated safely on a power cable having a ground fault circuit.

The compensation filter and the method for activating a compensation filter are not restricted to the embodiments and details shown and described. The compensation filter may contain further circuit elements, and the method may comprise additional method steps.

1-15. (canceled)

16. A compensation filter comprising:
a first port;
a second port;
a power supply line between the first port and the second port;
an electrical amplifier having an input and an output;
an output-coupling circuit connected between the power supply line and the input of the amplifier;
an input-coupling circuit connected between the output of the amplifier and the power supply line; and
a time switch,
wherein the compensation filter is configured to attenuate an instance of a common-mode interference in the power supply line, and
wherein the time switch is connected in series with the input-coupling circuit between the output of the amplifier and the power supply line.

17. The compensation filter according to claim 16, wherein the input-coupling circuit comprises a capacitive element.

18. The compensation filter according to claim 17, wherein a capacitance value of the capacitive element is large enough so that leakage currents below 1 kHz are compensated for.

19. The compensation filter according to claim 16, wherein the output-coupling circuit comprises a first inductive element and a second inductive element, which is magnetically coupled to the first inductive element.

20. The compensation filter according to claim 16,
wherein the amplifier comprises an operational amplifier,
wherein a first resistive element is coupled between input-coupling circuit and the output of the amplifier, and
wherein a second resistive element is connected between the input-coupling circuit and the input of the amplifier.

21. The compensation filter according to claim 16, wherein the compensation filter is configured to transmit a compensation signal with the same frequency, the same amplitude and inverse sign when the instance of the common-mode interference in the power supply line occurs.

22. The compensation filter according to claim 16, wherein the common-mode interference starts in a critical frequency range above a grid frequency.

23. The compensation filter according to claim 16, wherein the common-mode interference contains a leakage current.

24. The compensation filter according to claim 16, further comprising a supply circuit for the amplifier and/or the time switch.

25. The compensation filter according to claim 16, wherein the time switch comprises a relay and an actuating circuit for the relay.

26. The compensation filter according to claim 25, wherein the actuating circuit is configured to operate autonomously.

27. The compensation filter according to claim 25,
wherein the actuating circuit is connected to the relay, and
wherein the actuating circuit comprises a power supply connection and a series RC network.

28. The compensation filter according to claim 27, wherein the actuating circuit further comprises a first diode, a second resistive element, and a second diode.

29. The compensation filter according to claim 16, wherein the time switch is configured to couple the output of the amplifier to the power supply line only after a delay of 0.1 s or more after the compensation filter is turned on.

30. A method for activating a compensation filter having an amplifier and a power supply line, the method comprising:
coupling the power supply line to a power source and/or to an electrical load; and
delaying a coupling between amplifier and power supply line.
